(19) United States
(12) Patent Application Publication
(10) Pub. No.: US 2007/0034899 A1
(43) Pub. Date: Feb. 15, 2007

(54) Silicon-on-insulator photodiode optical monitoring system for color temperature control in solid state light systems

(75) Inventors: John Petruzzello, Carmel, NY (US); Theodore Letavic, Putnam Valley, NY (US); Benoit Robert Veillette, Portland, OR (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N. V., Eindhoven (NL)

(21) Appl. No.: 10/572,611

(22) PCT Filed: Sep. 15, 2004
(86) PCT No.: PCT/IB04/51773

§ 371 Date: Mar. 17, 2006

Related U.S. Application Data
(60) Provisional application No. 60/504,453, filed on Sep. 19, 2003.

(51) Int. Cl. H01L 31/00

(52) U.S. Cl. 257/186

(57) ABSTRACT

A silicon-on-insulator (SOI) photodiode optical monitoring method and system for color temperature control in solid state light systems. The method includes the steps of providing a plurality of SOI photodiodes, wherein each SOI photodiode includes a silicon substrate, a buried oxide layer formed on the silicon substrate, and a silicon layer formed on the buried oxide layer, and wherein the silicon layer of each SOI photodiode has a different thickness, determining a proportion of incident light passing through each SOI photodiode to the silicon substrate with respect to wavelength and the thickness of the silicon layer, and calculating color component intensities of the incident light based on the determined proportions.

The present invention relates in general to solid state light systems, and more particularly, to a silicon-on-insulator photodiode optical monitoring system for color temperature control in solid state light systems.

Solid state white lamps are made by mixing the output of three (red, green and blue) or four (red, green, blue, and amber) different color light emitting diodes (LEDs). The intensities (current) of the individual color LEDs determine the color (i.e., the “whiteness”) of the lamp. The control of the color by means of current monitoring (electrical sensing) alone in the LEDs is not possible at present due to the changing output characteristics with time of the LEDs. Therefore, an optical monitoring (i.e., light sensing) system, capable of discriminating the intensities of individual LEDs (i.e., colors), is necessary.

Present optical monitoring system systems often use discrete photodiodes to monitor the intensities of the individual LEDs of a solid state white lamp. Color temperature determination is accomplished by sensing the individual colors of the LEDs (sequenced in time) or by using filters on the photodiodes. Unfortunately, the use of discrete photodiodes and external filters increases the part count of the lamp, the number of production steps required to produce the lamp, and, ultimately, the resultant cost of the lamp.

There is a need, therefore, for an optical monitoring system that is capable of determining the color temperature of a solid state white lamp with simultaneous illumination of all lamp LEDs and without the use of external filters. In addition, there is a need for an optical monitoring system comprising a plurality of photodiodes that can be integrated with the driving electronics of a solid state lamp, and formed using the same process, thereby reducing the part count and cost of the lamp. Further, there is a need for an optical monitoring system comprising a plurality of photodiodes that can be produced with a silicon-on-insulator (SOI) process and that have an incident light wavelength dependent output signal. This signal can be used to uniquely determine and adjust the color content of the mixed light from the LEDs of the lamp.

The present invention provides a silicon-on-insulator photodiode optical monitoring system for color temperature control in solid state light systems. The present invention also provides a method for forming the silicon-on-insulator photodiode optical monitoring system.

In a first aspect, the present invention provides a method for forming a silicon-on-insulator (SOI) photodiode optical monitoring system, comprising: providing a plurality of SOI photodiodes, wherein each SOI photodiode includes a silicon substrate, a buried oxide layer formed on the silicon substrate, and a silicon layer formed on the buried oxide layer, and wherein the silicon layer of each SOI photodiode has a different thickness; determining a proportion of incident light passing through each SOI photodiode to the silicon substrate with respect to wavelength and the thickness of the silicon layer; and calculating color component intensities of the incident light based on the determined proportions.

In a second aspect, the present invention provides a silicon-on-insulator (SOI) photodiode, comprising: a silicon substrate having a first portion doped with a first dopant type and a second portion doped with a second dopant type, the first and second portions forming a pn-junction; a buried oxide layer formed on the silicon substrate; a silicon layer formed on the buried oxide layer, wherein an amount of incident light passing through the SOI photodiode to the silicon substrate with respect to wavelength is proportional to a thickness of the silicon layer; a field oxide layer formed on the silicon layer, wherein a thickness of the field oxide layer controls the thickness of the silicon layer; a trench extending to the silicon substrate; and a contact formed in the trench.

In a third aspect, the present invention provides a method of forming a silicon-on-insulator (SOI) photodiode, comprising: providing an SOI structure including a silicon substrate, a buried oxide layer formed on the silicon substrate; a silicon layer formed on the buried oxide layer, and a field oxide layer formed on the silicon layer; adjusting a thickness of the silicon layer by adjusting a thickness of the field oxide layer, wherein an amount of incident light passing through the SOI photodiode to the silicon substrate with respect to wavelength is proportional to the thickness of the silicon layer, forming a trench to expose a portion of the silicon substrate; and forming a contact in the trench.

These and other features of this invention will be more readily understood from the following detailed description of the various aspects of the invention taken in conjunction with the accompanying drawings in which:

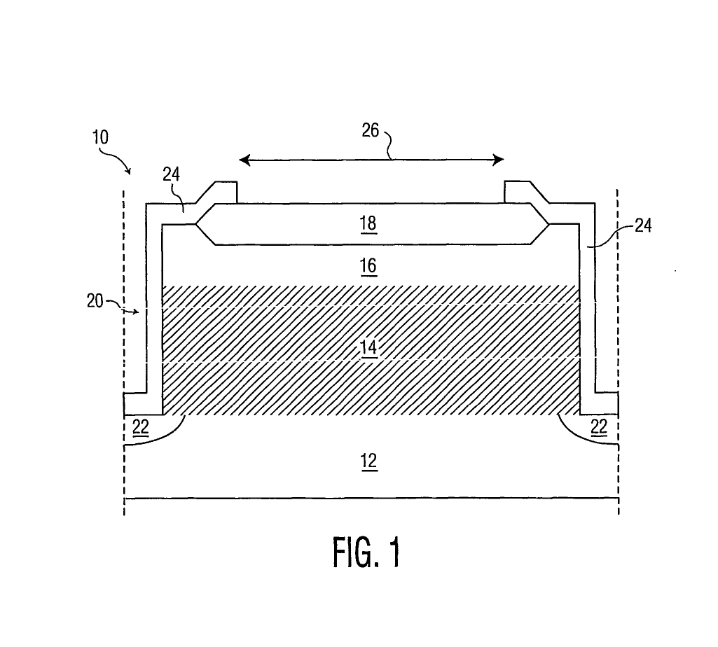

FIG. 1 is a cross-sectional view of an SOI photodiode produced in accordance with an embodiment of the present invention.

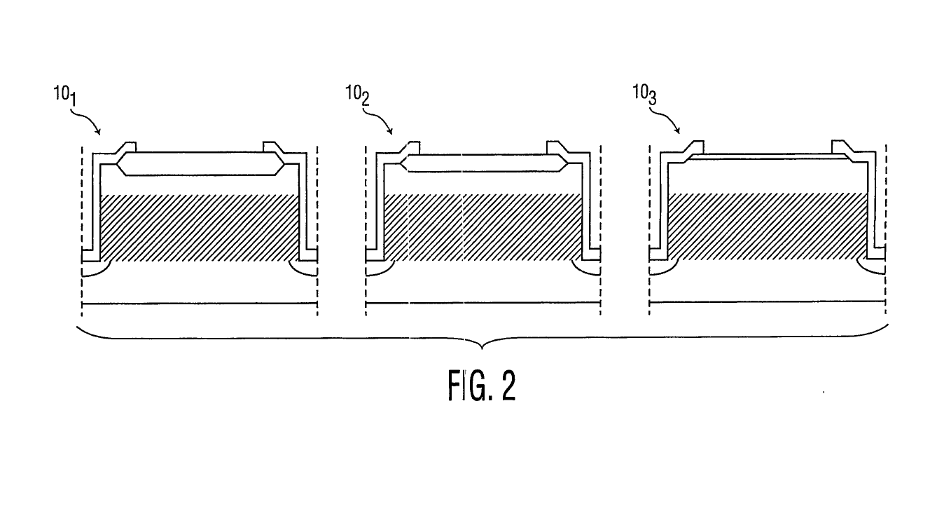

FIG. 2 illustrates an optical monitoring system comprising three SOI photodiodes in accordance with the present invention.

FIG. 3 is a cross-sectional view of an SOI photodiode produced in accordance with another embodiment of the present invention.

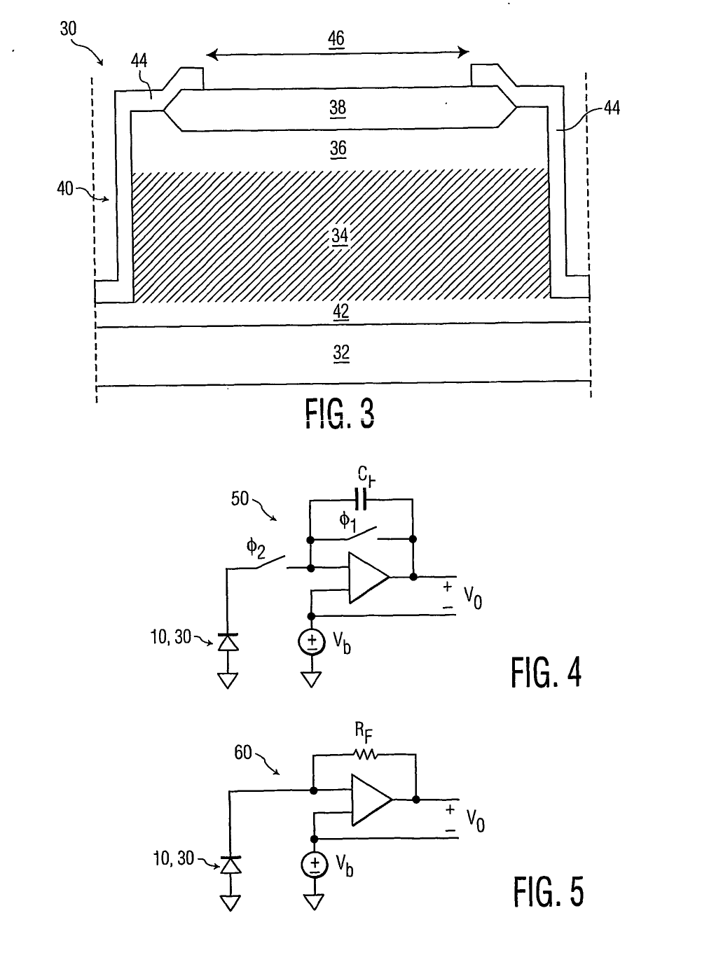

FIGS. 4 and 5 illustrate exemplary circuits for translating the voltage across the SOI photodiodes of the present invention into electrical quantities suitable for processing.

It should be noted that the drawings are merely schematic representations, not intended to portray specific parameters of the invention. The drawings are intended to depict only typical aspects of the invention, and therefore should not be considered as limiting the scope of the invention.

An SOI photodiode 10 in accordance with the present invention is illustrated in FIG. 1. The SOI photodiode 10 is produced using a standard SOI structure comprising an n-type silicon substrate 12, a buried oxide (BOX) layer 14 formed on the n-type silicon substrate 12, a silicon layer 16 formed on the BOX layer 14, and a field oxide layer 18 formed on the silicon layer 16. The SOI structure is typically provided on an SOI wafer. It should be noted that the control electronics for the LEDs are typically formed in the silicon layer 16 of other sections of the SOI wafer. The SOI structure is produced using well known techniques and will not be described in further detail.

A trench 20 is formed in the SOI structure using standard etching techniques. The trench 20 extends down through the SOI structure to the n-type silicon substrate 12. A p+ region 22 is implanted using known techniques via the trench 20 into the n-type silicon substrate 12. The pn-junction of the SOI photodiode 10 is formed at the interface of the p+ region 22 and the n-type silicon substrate 12, wherein the p+ region 22 forms the anode of the photodiode 10 and the n-type silicon substrate 12 forms the cathode of the photodiode 10. A p+ metal contact 24 is then formed using known techniques on the p+ region 22, along the sides of the SOI structure, and partially over the top surface of the field oxide layer 18. As seen in FIG. 1, the p+ metal contact 24 forms the photodiode aperture 26 of the SOI photodiode 10. The p+ metal contact 24 also provides a contact to the p+ region 22 (i.e., the anode of the SOI photodiode 10). A corresponding contact (not shown) is provided for the n-type silicon substrate 12 (i.e., the anode of the SOI photodiode 10).

The silicon layer 16 of the SOI photodiode 10 is used as a light filter (long wavelength pass). Light having a wavelength of interest passes through the photodiode aperture 26, the field oxide layer 18, the silicon layer 16, the BOX layer 14, into the n-type substrate, and generates electron-hole pairs (EHPs) in the n-type silicon substrate 12 of the SOI photodiode 10. The EHPs are then collected by their respective contacts (electrons to the cathode contact (not shown) and holes to the p+ metal contact 26), producing a voltage (open circuit) or current (short circuit). The amount of current is proportional to the number of generated EHPs, which is proportional to the incident light intensity.

Color discrimination is achieved in the SOI photodiode 10 of the present invention by using the silicon layer 16 as a long pass filter, wherein a thickness of the silicon layer 16 determines the proportion of incident light that passes through to the n-type silicon substrate 12. The silicon layer 16 can be produced with varying thicknesses by adjusting the depth to which the field oxide layer 18 is grown into the silicon layer 16. In accordance an embodiment of the present invention as illustrated in FIG. 2, the silicon layer 16 can be produced with standard SOI process thicknesses of 0.4, 0.9, and 1.4 μm, to produce an optical monitoring system comprising three SOI photodiodes 101, 102, and 103, respectively. Such an optical monitoring system can be used to monitor white light produced using three LEDs (i.e., blue, green, and red). It should be noted that these thicknesses are only intended to represent one of many possible sets of thicknesses that can be used in the practice of the present invention. Further, although the optical monitoring system illustrated in FIG. 2 includes three SOI photodiodes 101, 102, and 103, a fourth SOI photodiode (not shown) may be used if the white light is produced using four LEDs (i.e., blue, green, red, and amber).

The proportion of the incident light that makes it through to the n-type silicon substrate 12 with respect to the wavelength, λm and the thickness of the silicon layer 16, x, is equal to e^{-a}_{λ}^{x}, where al is the absorption coefficient of the silicon layer 16. The following table lists this proportion for different wavelengths λ of incident light and different silicon layer 16 thicknesses x, for three SOI photodiodes 10 having silicon layer 16 thicknesses of 0.4, 0.9 and 1.4 μm:

| Wavelength | Silicon thickness (μm) | | |
|---|---|---|---|
| (nm) | 0.4 | 0.9 | 1.4 |
| 470 (blue) | 0.51 | 0.22 | 0.09 |
| 540 (green) | 0.73 | 0.50 | 0.34 |
| 610 (red) | 0.86 | 0.70 | 0.58 |

The color components can be extracted from light incident on the three SOI photodiodes 10 with different silicon layer 16 thicknesses, since it results in a system with three equations and three unknowns. More formally, if the above matrix of light filtering coefficients is denoted Λ and the vector representing the color content of the incident light is labeled c, then the vector of the photodiodes signals, i, will be equal to i=Λ*c. To recover the color components, the equation c=Λ⁻¹*i may be used.

An alternative embodiment of an SOI photodiode 30 in accordance with the present invention, having better light sensitivity than the SOI photodiode 10, is illustrated in FIG. 3. The SOI photodiode 30 comprises an n-type silicon substrate 32, a buried oxide (BOX) layer 34, a silicon layer 36 formed on the BOX layer 34, and a field oxide layer 38 formed on the silicon layer 36. In this embodiment, a vertical pn-junction is formed in the n-type silicon substrate 32 prior to processing the silicon layer 36 (e.g., during manufacture of SOI wafer). In particular, a p+ region 42 is formed by p+ doping a top section of the n-type silicon substrate 32 using any suitable doping technique. The BOX layer 34, a silicon layer 36, and field oxide layer 38 are then formed in a known manner on the p+ region 42 to form an SOI structure. The pn-junction of the SOI photodiode 30 has a larger area than the pn-junction of the SOI photodiode 10, which makes the SOI photodiode 30 more sensitive to incident light. The SOI photodiode 30 produced by this method can be isolated from adjacent circuits by suitably patterning the p+ region 42 or etching through to the n-type silicon substrate 32.

A trench 40 is formed in the SOI structure using standard etching techniques. The trench 40 extends down through the SOI structure to the p+ region 42. A p+ metal contact 44 is then formed using known techniques on the p+ region 42, along the sides of the SOI structure, and partially over the top surface of the field oxide layer 38. As seen in FIG. 3, the p+ metal contact 44 forms the photodiode aperture 46 of the SOI photodiode 30. The p+ metal contact 44 also provides a contact to the p+ region 42 (i.e., the anode of the SOI photodiode 30). A corresponding contact (not shown) is provided for the n-type silicon substrate 32 (i.e., the cathode of the SOI photodiode 30).

The silicon layer 36 of the SOI photodiode 30 is used as a light filter (long wavelength pass). Light having a wavelength of interest passes through the photodiode aperture 46, the silicon layer 36, and the BOX layer 34, and generates electron-hole pairs (EHPs) in the n-type silicon substrate 32 of the SOI photodiode 30. The EHPs are then collected by their respective contacts (electrons to the cathode contact (not shown) and holes to the p+ metal contact 44), producing a voltage (open circuit) or current (short circuit). The amount of current is proportional to the number of generated EHPs, which is proportional to the incident light intensity. Color discrimination is achieved in the SOI photodiode 30 of the present invention by using the silicon layer 36 as a long pass filter, in a manner similar to that detailed above with regard to the SOI photodiode 10.

A first circuit 50 for translating the charge across the SOI photodiode 10, 30, into electrical quantities suitable for processing is illustrated in FIG. 4. In the circuit 50, a discrete-time charge read-out is performed using a switched-capacitor delay element Cf. Vb is a voltage source that ensures that the SOI photodiode 10, 30, remains reverse-biased. There are two phases in the operation of the circuit 50. In phase one, the switch 02 is open while Φ₁ is closed. This forces the capacitor C_{F} to discharge. In the second phase, the switch Φ₁ is open while Φ₂ is closed. As a result, the charge accumulated on the SOI photodiode 10, 30, is transferred to the capacitor C_{F} and converted to an output voltage Vₒ according to the equation Vₒ=Q/C_{F}, where Q is the charge. This cycle may be repeated as necessary.

Continuous reading of the charge across the SOI photodiode 10, 30, amounts to the conversion of a current into a voltage. A simple circuit 60 for this purpose is shown in FIG. 5. In this circuit, the output voltage Vₒ is equal to Vₒ=I*R_{F}, where I is the current from the SOI photodiode 10, 30.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

1. A method for forming a silicon-on-insulator (SOI) photodiode optical monitoring system, comprising:
providing a plurality of SOI photodiodes (10; 30), wherein each SOI photodiode includes a silicon substrate (12; 32), a buried oxide layer (14; 34) formed on the silicon substrate, and a silicon layer (16; 36) formed on the buried oxide layer, and wherein the silicon layer of each SOI photodiode has a different thickness;
determining a proportion of incident light passing through each SOI photodiode (10; 30) to the silicon substrate (12; 32) with respect to wavelength and the thickness of the silicon layer (16; 36); and
calculating color component intensities of the incident light based on the determined proportions.

2. The method of claim 1, wherein each SOI photodiode (10; 30) further comprises a field oxide layer (18; 38) on the silicon layer (16; 36), and wherein the different thickness of the silicon layer of each SOI photodiode is provided by varying a thickness of the field oxide layer.

3. The method of claim 1, wherein the silicon substrate (12; 32) is doped with a dopant of a first type, and wherein each SOI photodiode (10; 30) is formed by:
forming a trench (20; 40) through the silicon layer (16; 36) and the buried oxide layer (14; 34) to expose a portion of the silicon substrate;
doping the exposed portion of the silicon substrate with a dopant of a second type to form a pn-junction; and
forming a contact (24, 44) in the trench.

4. The method of claim 3, wherein the contact (24; 44) forms an aperture (26; 46) of the SOI photodiode (10; 30).

5. The method of claim 1, wherein the proportion of incident light is given by e^{-a}_{λ}^{x}, where a_{λ} is an absorption coefficient of the silicon layer (16; 36) and x is the thickness of the silicon layer.

6. The method of claim 1, further comprising:
forming a vertical pn-junction in the silicon substrate (32).

7. The method of claim 6, wherein each SOI photodiode (30) is formed by:
forming a trench (40) through the silicon layer (36) and the buried oxide layer (34) to expose a portion of the silicon substrate (32); and
forming a contact (44) in the trench.

8. The method of claim 6, wherein the contact (44) forms an aperture (46) of the SOI photodiode (30).

9. A silicon-on-insulator (SOI) photodiode (10; 30), comprising:
a silicon substrate (12; 32) having a first portion doped with a first dopant type and a second portion doped with a second dopant type, the first and second portions forming a pn-junction;
a buried oxide layer (14; 34) formed on the silicon substrate;
a silicon layer (16; 36) formed on the buried oxide layer, wherein an amount of incident light passing through the SOI photodiode to the silicon substrate with respect to wavelength is proportional to a thickness of the silicon layer;
a field oxide layer (18; 38) formed on the silicon layer, wherein a thickness of the field oxide layer controls the thickness of the silicon layer;
a trench (20; 40) extending to the silicon substrate; and
a contact (24; 44) formed in the trench.

10. The SOI photodiode (30) of claim 9, wherein the pn-junction is a vertical pn-junction.

11. The SOI photodiode (30) of claim 9, wherein the proportion of incident light passing through the SOI photodiode to the silicon substrate (32) is given by e^{-a}_{λ}^{x}, where a_{λ} is an absorption coefficient of the silicon layer (36) and x is the thickness of the silicon layer.

12. The SOI photodiode (30) of claim 9, wherein the contact (44) forms an aperture (46) of the SOI photodiode.

13. A method of forming a silicon-on-insulator (SOI) photodiode (10; 30), comprising:
providing an SOI structure including a silicon substrate (12; 32), a buried oxide layer (14; 34) formed on the silicon substrate; a silicon layer (16; 36) formed on the buried oxide layer, and a field oxide layer (18; 38) formed on the silicon layer;
adjusting a thickness of the silicon layer by adjusting a thickness of the field oxide layer, wherein an amount of incident light passing through the SOI photodiode to the silicon substrate with respect to wavelength is proportional to the thickness of the silicon layer;
forming a trench (20; 40) to expose a portion of the silicon substrate; and
forming a contact (24; 44) in the trench.

14. The method of claim 13, wherein, prior to forming the contact (24), doping the exposed portion of the silicon substrate (12) with a dopant to form a pn-junction.

15. The method of claim 13, wherein the silicon substrate (32) comprises a vertical pn-junction.
